(19) United States
(12) Patent Application Publication
(10) Pub. No.: US 2023/0169222 A1
(43) Pub. Date: Jun. 1, 2023

(54) POLLUTANT SENSOR PLACEMENT

(71) Applicant: Microsoft Technology Licensing, LLC, Redmond, WA (US)

(72) Inventors: Shirui WANG, Houston, TX (US); Sara MALVAR MAUA, Sao Paulo (BR); Leonardo DE OLIVEIRA NUNES, Rio De Janeiro (BR); Kim D. WHITEHALL, Redmond, WA (US); Yagna Deepika ORUGANTI, Houston, TX (US); Yazeed ALAUDAH, Houston, TX (US); Anirudh BADAM, Issaquah, WA (US); Mirco MILLETARI, Singapore (SG)

(73) Assignee: Microsoft Technology Licensing, LLC, Redmond, WA (US)

(21) Appl. No.: 17/726,206

(22) Filed: Apr. 21, 2022

Related U.S. Application Data
(60) Provisional application No. 63/284,327, filed on Nov. 30, 2021.

(51) Int. Cl. G06F 30/13

(52) U.S. Cl. CPC G06F 30/13

(57) ABSTRACT

A method for pollutant sensor placement for pollutants from point sources is described. Data about environmental characteristics for a geographic region are received from a plurality of environmental sensors. The geographic region includes pollutant sources that emit a pollutant. The received data from one or more of the plurality of environmental sensors are transformed into common data having a common spatial and temporal discretization across the geographic region. Predicted emission plumes are generated for the pollutant sources within the geographic region that identify pollutant detection regions for the pollutant when the pollutant is emitted by the pollutant sources using the common data. Sensor locations for a plurality of pollutant sensors are greedily selected across the common spatial and temporal discretization according to a number of predicted emission plumes that are detectable by the plurality of pollutant sensors.

### CROSS REFERENCES TO RELATED APPLICATIONS

This application claims the benefit of U.S. Provisional Pat. Application No. 63/284,327, entitled “Unsupervised Machine Learning Framework for Sensor Placement,” filed on Nov. 30, 2021, which is hereby incorporated herein by reference in its entirety.

### BACKGROUND

Extensive efforts have been made to improve detection and remediation of atmospheric leaks of pollutants such as methane, which is a potent greenhouse gas. Methane sources that leak into the atmosphere may include oil and gas industry infrastructure (e.g., equipment and industrial sites for production, processing, transmission, storage, and distribution), as well as agricultural sites, landfills, and abandoned oil and gas fields. There are a variety of pollutant-sensing technologies being deployed, with varying instrumentation and techniques, sensitivities, spatial and temporal resolution, and price of acquisition. These technologies include satellites, aerial surveys, Internet of Things (IoT) sensor grids, unmanned vehicles, and other sensors. Satellite data, for example, from Sentinel-SP TROPOMI may have coarse spatial resolution and low methane detection sensitivity but near-daily global coverage for detecting methane from point sources. Aircraft surveys, on the other hand, may provide a much richer picture of an area of interest with higher spatial resolution, but such surveys are intermittent. Ground sensors may provide real-time data streams, but may have a high cost associated with deploying sensors to cover large swaths of land and/or vertical coverage (e.g., elevation).

It is with respect to these and other general considerations that aspects have been described. Also, although relatively specific problems have been discussed, it should be understood that the aspects should not be limited to solving the specific problems identified in the background.

### SUMMARY

Aspects of the present disclosure are directed to placement of sensors for pollutant detection from polluting point sources.

In one aspect, a method for pollutant sensor placement is provided. The method includes: receiving data about environmental characteristics for a geographic region from a plurality of environmental sensors, wherein the geographic region includes pollutant sources that emit a pollutant; transforming the received data from one or more of the plurality of environmental sensors into common data having a common spatial and temporal discretization across the geographic region; generating for the pollutant sources predicted emission plumes within the geographic region using the common data, wherein the predicted emission plumes identify pollutant detection regions for the pollutant when the pollutant is emitted by the pollutant sources; and greedily selecting sensor locations for a plurality of pollutant sensors across the common spatial and temporal discretization according to a number of predicted emission plumes that are detectable by the plurality of pollutant sensors at the selected sensor locations. In some aspects, at least some of the data is received from data sources that process data from environmental sensors. In some aspects, the common spatial and temporal discretization corresponds to a common time discretization, for example, timestamps for 10 second time intervals, 10 minute time intervals, etc.

In another aspect, a method for pollutant sensor placement is provided. The method includes: receiving data about environmental characteristics for a geographic region from a plurality of environmental sensors, wherein the geographic region includes pollutant sources that emit a pollutant; transforming the received data from one or more of the plurality of environmental sensors into common data having a common spatial and temporal discretization across the geographic region; generating, for the pollutant sources, predicted emission plumes within the geographic region using the common data, wherein the predicted emission plumes identify pollutant detection regions for the pollutant when the pollutant is emitted by the pollutant sources; spatially clustering the overlapping predicted emission plumes into emission clusters; identifying a list of centroids of the emission clusters; and greedily selecting sensor locations for a plurality of pollutant sensors as centroids from the list of centroids according to a number of predicted emission plumes that are detectable by the plurality of pollutant sensors at the selected sensor locations. In some aspects, at least some of the data is received from data sources that process data from environmental sensors. In some aspects, the common spatial and temporal discretization corresponds to a common time discretization, for example, timestamps for 10 second time intervals, 10 minute time intervals, etc.

In yet another aspect, a system for pollutant sensor placement is provided. The system includes a staging database configured to receive data about environmental characteristics for a geographic region from a plurality of environmental sensors. The geographic region includes pollutant sources that emit a pollutant. The system further includes a sensor data processor configured to transform the received data from one or more of the plurality of environmental sensors into common data having a common spatial and temporal discretization across the geographic region. The system also includes a deployment processor configured to: generate, for the pollutant sources, predicted emission plumes within the geographic region that identify pollutant detection regions for the pollutant when the pollutant is emitted by the pollutant sources using the common data; and greedily select sensor locations for a plurality of pollutant sensors across the common spatial and temporal discretization according to a number of predicted emission plumes that are detectable by the plurality of pollutant sensors at the selected sensor locations. In some aspects, at least some of the data is received from data sources that process data from environmental sensors. In some aspects, the common spatial and temporal discretization corresponds to a common time discretization, for example, timestamps for 10 second time intervals, 10 minute time intervals, etc.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS/FIGURES

Non-limiting and non-exhaustive examples are described with reference to the following Figures.

FIG. 1 shows a block diagram of an example of an environmental sensor system configured to determine locations for placement of pollutant sensors, according to aspects of the present disclosure.

FIG. 2 shows a diagram of an example of a geographic region for placement of pollutant sensors, according to aspects of the present disclosure.

FIG. 3A shows a diagram of another example of a geographic region for placement of pollutant sensors, according to aspects of the present disclosure.

FIG. 3B shows a diagram of an example common spatial and temporal discretization for the geographic region of FIG. 3A, according to aspects of the present disclosure.

FIG. 4 shows a flowchart of an example method for pollutant sensor placement for pollutants from point sources, according to aspects of the present disclosure.

FIG. 5 shows a flowchart of another example method for pollutant sensor placement for pollutants from point sources, according to aspects of the present disclosure.

FIG. 6 is a block diagram illustrating example physical components of a computing device with which aspects of the disclosure may be practiced.

FIGS. 7 and 8 are simplified block diagrams of a mobile computing device with which aspects of the present disclosure may be practiced.

### DETAILED DESCRIPTION

In the following detailed description, references are made to the accompanying drawings that form a part hereof, and in which are shown by way of illustrations specific aspects or examples. These aspects may be combined, other aspects may be utilized, and structural changes may be made without departing from the present disclosure. Aspects may be practiced as methods, systems, or devices. Accordingly, aspects may take the form of a hardware implementation, an entirely software implementation, or an implementation combining software and hardware aspects. The following detailed description is therefore not to be taken in a limiting sense, and the scope of the present disclosure is defined by the appended claims and their equivalents.

The present disclosure describes various examples of computing devices and method for determining locations for placement of pollutant sensors. For example, a computing device receives data from pollutant source, environmental sensors, and/or external data sources and determines suitable locations for placement of pollutant sensors. In some aspects, the computing device also determines a number of pollutant sensors to be placed and/or characteristics of the pollutant sensors. The characteristics may include detection type, pollutant detection sensitivities, spatial resolution, temporal resolution, purchase cost, maintenance cost, and/or other suitable characteristics. In some scenarios, the pollutant sensors detect the presence or measure levels of pollutants such as methane or other greenhouse gases.

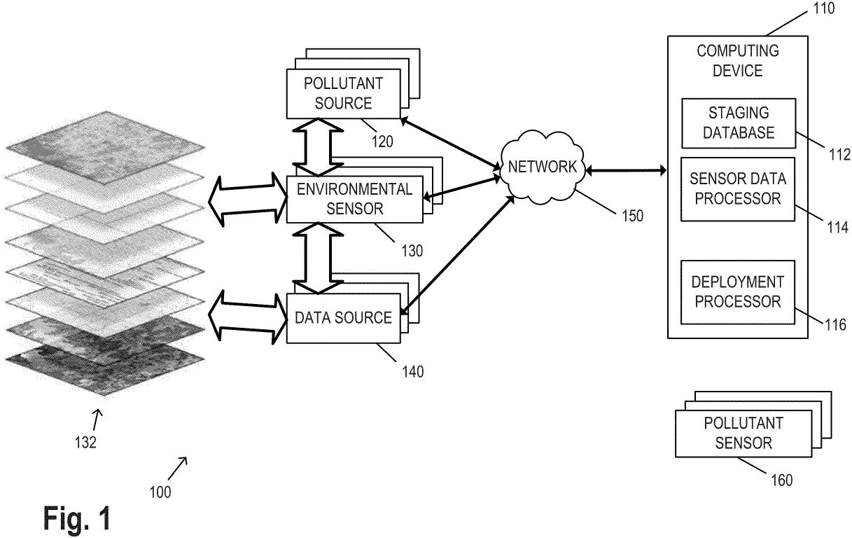

This and many further aspects of a computing device are described herein. For instance, FIG. 1 shows a block diagram of an example of an environmental sensor system 100 (hereinafter, “system 100”) configured to determine locations for placement of pollutant sensors 160, according to an example embodiment. The environmental sensor system 100 comprises a computing device 110, one or more pollutant sources 120, and one or more environmental sensors 130. In some aspects, the system 100 also includes one or more data sources 140. At least some of the computing device 110, pollutant sources 120, environmental sensors 130, and data sources 140 may be communicatively coupled by a network 150.

Computing device 110 may be any type of computing device, including a mobile computer or mobile computing device (e.g., a Microsoft® Surface® device, a laptop computer, a notebook computer, a tablet computer such as an Apple iPad™, a netbook, etc.), or a stationary computing device such as a desktop computer or PC (personal computer). In some aspects, computing device 110 is a network server, cloud server, or other suitable distributed computing system. Computing device 110 may be configured to execute one or more software applications (or “applications”) and/or services and/or manage hardware resources (e.g., processors, memory, etc.), which may be utilized by users (e.g., customers) of the computing device 110.

The pollutant sources 120 may comprise ground locations, buildings, equipment (e.g., fixed industrial equipment), underwater or underground locations (e.g., pumps, pipelines), that may leak one or more pollutants, in various aspects. In general, a pollutant as used herein is a substance that has undesired effects on an environment, or adversely affects the usefulness of a resource or device. In some aspects, the pollutants may include greenhouse gases (GHG) such as methane, nitrous oxide, ozone, carbon dioxide, or other gases that contribute to a “greenhouse effect.” In other aspects, the pollutants may include other airborne pollutants, such as carbon monoxide, hydrocarbons (e.g., petroleum, natural gas), other gases, liquids (e.g., gasoline, kerosene), vapors, aerosols, particulate matter (e.g., soot from internal combustion engines, coal dust), or other chemicals and compounds. In still other aspects, the pollutants may be other substances, even those generally considered beneficial (such as breathable oxygen or potable water), that are being emitted in an undesirable area, such as water leaks from a device that generates or filters water, or oxygen leaks from a pressurized habitat for humans.

For ease of discussion, the aspects herein are described with methane as a pollutant. However, the aspects herein apply with other airborne pollutants, such as those described above. Accordingly, the pollutant sources 120 may include oil and gas industry infrastructure (e.g., equipment and industrial sites for production, processing, transmission, storage, and distribution), as well as agricultural sites, landfills, and abandoned oil and gas fields. Examples of oil and gas infrastructure include pipelines, tank batteries, compressor stations, well pads, their supporting equipment, and the like. In other aspects for different pollutants, the pollutant sources 120 may be chemical plants, factories or manufacturing sites, or other industrial or commercial infrastructure.

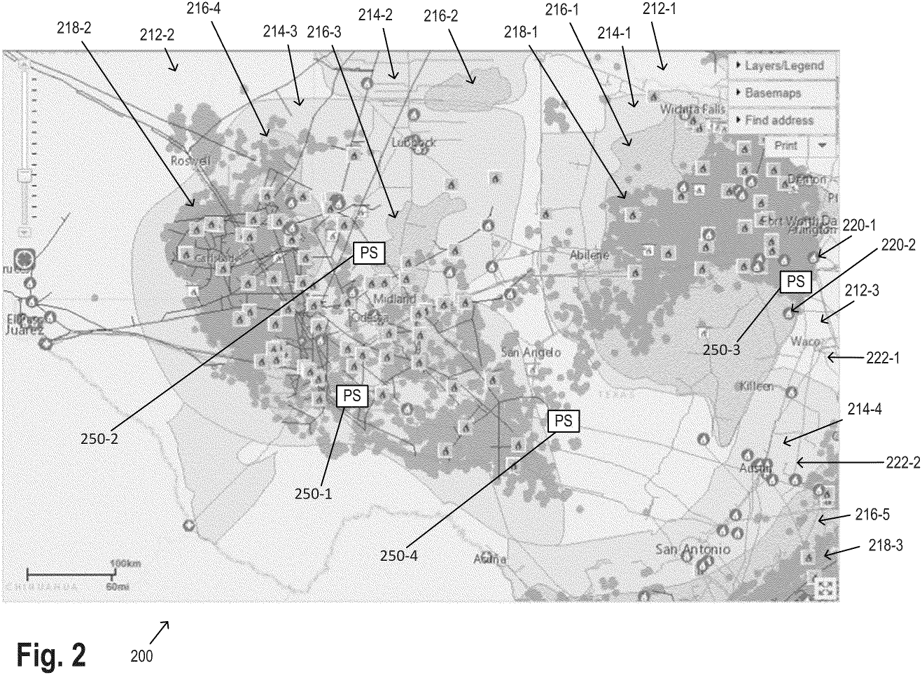

The pollutant sources 120 are generally spread out over a geographic region or region of interest, such as geographic region 200 shown in FIG. 2. Each pollutant source 120 may leak pollutants at varying levels and times. Generally, emissions from different pollutant sources 120 may have different characteristics when analyzed using time series data. The emissions from pneumatic controllers, chemical injection pumps, and/or from water flashing (e.g., release of methane dissolved in water when released to the atmosphere) may exhibit short term temporal variability, long term variability, and/or diurnal periodicity, in various scenarios. For example, a pollutant source 120 may emit a constant, low level of methane over time. As another example, where the pollutant source 120 is a compressor that compresses methane into liquid form, it may have an intermittent, moderate level leak that begins when pressure exceeds a limit of a valve seal. As yet another example, where the pollutant source 120 is a pipeline that transports methane gas, it may have a leak that starts after a long period of time without leaks (e.g., beginning to leak after several years in service). Still other pollutant sources 120 may be designed to never leak or exceed design parameters for leakage, but may still be monitored for leaks and/or excessive leakage due to deterioration, accidents (e.g., collisions with other equipment), vandalism, etc.

The environmental sensors 130 are sensors that measure and/or detect the presence of an environmental characteristic and provide corresponding data, such as various layers of environmental map data 132. Generally, the environmental sensors 130 provide data related to environmental characteristics within the geographic region 200, or nearby regions that may affect dispersion of a pollutant within the geographic region 200. In some aspects, environmental sensors 130 may be carried to a sensing location by a vehicle, such as a satellite, drone, plane, atmospheric research vehicle, or other suitable vehicle. In other aspects, the environmental sensors 130 are provided in fixed locations.

In various aspects, the environmental sensors 130 measure and/or detect environmental characteristics related to dispersion of the pollutants emitted by the pollutant sources 120. Where the pollutant is methane, for example, the environmental sensors 130 may measure and/or detect methane concentration, ambient temperature, humidity, wind speed and direction, and other suitable environmental characteristics. In some aspects, the environmental sensors 130 provide different measurements at two or more varying heights (e.g., with multiple readings at different times), for example, at ground level, cloud level, every 50 meters, etc. Moreover, some environmental sensors 130 may provide data with different temporal resolutions, for example, providing measurements in real-time, five minute intervals, every four hours, daily, monthly, etc. In the aspects described herein with respect to methane as the pollutant, the environmental sensors 130 may comprise optical gas imaging cameras (forward looking infrared, nondispersive infrared), catalytic detection sensors, satellites, aerial surveys, Internet of Things (IoT) sensors, unmanned vehicles (e.g., aerial drones or ground-based vehicles), fixed sensors attached to the pollutant sources 120, or other suitable sensors.

Some environmental sensors 130 may be located within a vicinity of, coupled with, or integral to a pollutant source 120. For example, an environmental sensor 130 that measures ambient temperature and pressure may be integral to a compressor (i.e., pollutant source 120) that compresses methane into liquid form. As another example, an environmental sensor that measures methane levels may be located within 5 meters, 20 meters, or another suitable distance from a well pad. Some environmental sensors 130 may be standalone or independent sensors, such as hand-held optical gas imaging cameras or soil moisture sensors. Some environmental sensors 130 may be part of a sensor package that combines several sensors, for example, a sensor package that measures temperature, wind speed, and wind direction. In some aspects, the environmental sensors 130 are small, inexpensive sensors, such as Internet of Things sensors, that form a mesh of data streams that may be analyzed in near real-time to accurately detect anomalous emissions and identify the source of leaks.

Aerial imagery or data may be captured using cameras, light detection and ranging (LiDAR) equipment, gas spectrometers, or other suitable detectors as the environmental sensors 130. This data may be available monthly, or at 3-month intervals, other suitable intervals, or on demand, for example, due to generally higher operating costs (e.g., for fuel, pilot fees, aircraft maintenance, etc.). Unmanned vehicles may utilize laser absorption spectroscopy, cavity-enhanced laser spectroscopy, or other suitable sensors as the environmental sensors 130. In an embodiment, an autonomous or semi-autonomous drone may fly along a pre-planned path and gather data near the ground at a regular cadence, for example, along a length of a pipeline.

The data sources 140 comprise databases, data sets, and/or compilations of data representing environmental characteristics, including detected pollutants, measured levels of pollutants, reported pollutant leaks, etc. In some aspects, the data sources 140 receive data from at least some of the environmental sensors 130 (e.g., satellites, aerial surveys, sensors at pollutant sources 120) and as such, data received from an environmental sensor 130 may be understood to include data from a data source 140 that has been previously provided by an environmental sensor 130 and further processed at or by the data source 140 (e.g., augmented, added to via interpolation, etc.) and may even include data that is based upon data from an environmental sensor 130. The data sources 140 may also utilize data from mapping services that provide geographical maps, topographical maps, ground cover maps, etc. Access to the data sources 140 may be provided by a government, commercial business or service, non-profit group, or other entity. In some aspects, the data sources 140 include a mapping service that provides geographical maps, topographical maps, ground cover maps, etc.

In some embodiments, the data sources 140 may comprise one or more of a land-use data source, pollutant facility data source, or a data source provided by the European Space Agency (e.g., providing Sentinel 2 data, Sentinel-5P data), National Aeronautics and Space Administration (Terra MODIS and Aqua MODIS data), GHGSat, a weather service (e.g., National Weather Service), National Oceanic and Atmospheric Administration (NOAA Operational Model Archive and Distribution System), Emissions Database for Global Atmospheric Research (EDGAR), United States Geological Survey (e.g., Landsat 8 data), Total Carbon Column Observing Network (TCCON), oil and gas production companies (e.g., ExxonMobil, Chevron), New Mexico Oil Conservation Division (e.g., providing reports of methane emissions, oil and gas infrastructure maps), Texas Rail Road Commission (e.g., providing reports of methane emissions, oil and gas infrastructure maps), and/or other suitable data source providers.

The computing device 110 includes a staging database 112, a sensor data processor 114, and a deployment processor 116. Generally, the computing device 110 is configured to receive data from the pollutant source 120, the environmental sensors 130, and/or the data sources 140 and determine suitable locations for placement of pollutant sensors 160. More specifically, the staging database 112 receives data from the pollutant sources 120, the environmental sensors 130, and/or the data sources 140. Data from the pollutant source 120 may include diagnostic and control information. For example, operators of the pollutant sources 120 (e.g., an energy production company, chemical production company, refinery) and/or control systems of the pollutant sources 120 may provide Supervisory Control And Data Acquisition (SCADA) data or other suitable information to the staging database 112. In some scenarios, the computing device 110 is configured to actively request updates from some of the pollutant sources 120, the environmental sensors 130, and/or the data sources 140, for example, on a suitable schedule (e.g., every week, every month). In other scenarios, the computing device 110 requests the updates in response to a user request.

The sensor data processor 114 is configured to perform processes that improve compatibility among data from different data sources 140 and different environmental sensors 130. For some of the data sources 140, the sensor data processor 114 may be configured to process data within the staging database 112 (i.e., after the data is received by the staging database 112) to have a common format, organization, etc. For some of the data sources 140, the sensor data processor 114 may be configured to receive and process data from the data sources 140 before storing the data within the staging database 112.

In some aspects, the sensor data processor 114 processes and/or transforms data into common data having a common format, common “grid lines” (e.g., regular grids, rectilinear grids, curvilinear grids), common coordinate systems (e.g., 2-dimensional, 3-dimensional), or common spatial and temporal discretization within the geographic region 200, a common temporal resolution (e.g., data is present at 1 hour intervals), common spatial resolution (e.g., data is present for each 50 m² area), and/or common elevation resolution (e.g., data is present for each 50 m elevation interval). In some scenarios, the sensor data processor 114 scales data to a coarser format (e.g., scaling 5 minute data to 20 minute data). In other scenarios, the sensor data processor 114 may interpolate existing data to generate new data to improve the compatibility. For example, a first set of data may have a temporal resolution of 5 minutes, while a second set of data may have a temporal resolution of 20 minutes, and the sensor data processor 114 may interpolate the second set of data to generate equivalent data at the temporal resolution of 5 minutes. As another example, a third data set may have a spatial resolution of 50 meters, while a fourth data set may have a spatial resolution of 250 meters, and the sensor data processor 114 may interpolate the fourth set of data to generate equivalent data at the spatial resolution of 50 meters. The sensor data processor 114 may be configured to perform bilinear interpolation, nearest neighbor interpolation, inverse distance interpolation, and/or other suitable interpolation techniques, in various aspects.

The deployment processor 116 is configured to determine locations within a geographic region (e.g., geographic region 200) for placement of the pollutant sensors 160 based on environmental characteristics (e.g., the data within the staging database 112). In some embodiments, the deployment processor 116 determines one or more of a number of pollutant sensors 160, locations of the pollutant sensors 160, and/or characteristics of the pollutant sensors 160. As one example, the deployment processor 116 determines a number of pollutant sensors 160 and locations for their placement to meet a desired level of detectability (e.g., detect leaks greater than 5 kg per hour) at a desired cost (e.g., $100,000 for sensors and installation). As another example, the deployment processor 116 determines a first number of high sensitivity sensors, a second number of low sensitivity sensors, and their respective locations to meet a desired level of detectability at a desired cost. Example characteristics of the pollutant sensors 160 may include detection type (e.g., infrared, gas spectrometry, etc.), pollutant detection sensitivities (e.g., 100 parts per million, 500 parts per million, etc.), spatial resolution (50 meters, 1000 meters, etc.), temporal resolution (real-time, 5 minute intervals, 4 hours, daily, monthly), purchase cost, maintenance cost, and/or other suitable characteristics.

Generally, the deployment processor 116 is configured to determine a sensor configuration (e.g., the number, locations, and/or characteristics of the pollutant sensors 160) to detect pollutant leaks or related anomalies. In some scenarios, the deployment processor 116 determines an optimal sensor configuration for a given set of constraints (e.g., price, detectability of the pollutant, etc.). The deployment processor 116 may be configurable to determine a sensor configuration based on adjustable criteria, for example, a number of simultaneous leaks that may be detected, a severity of leaks that can be detected (e.g., 1 kg/hr, 100 kg/hr), time until a leak is detected, likelihood of detection for leaks that exceed a safety threshold (e.g., likelihood of detecting a 100 kg/hr leak) within a predetermined time period (e.g., within 2 hours, 3 days, etc.), cost of the pollutant sensors 160, installation cost of the pollutant sensors 160, whether adjacent equipment (i.e., pollutant sources 120) need to be turned off or disabled for installation and/or maintenance of the pollutant sensor 160, and/or other suitable criteria. For example, a moderate leak may take several hours to reach detectable levels of a low-cost 1000 part per million (ppm) pollutant sensor 160, while a more expensive 100 ppm pollutant sensor 160 may detect the moderate leak within 10 minutes. Moreover, a large network of inexpensive pollutant sensors 160 may require a large labor cost for installation and maintenance, while similar performance in detectability may be achieved with fewer, but higher quality pollutant sensors 160. The deployment processor 116 may also select a pollutant sensor 160 based on its suitability for a particular sub-region in which it will be placed (i.e., an operating environment). For example, optical gas imaging cameras may be less susceptible to sensor poisoning but more sensitive to moisture and are generally more expensive to operate than a catalytic detection sensor, which may be subject to sensor poisoning but be less expensive to purchase and can resist higher humidity.

The deployment processor 116 may be configured to determine a sensor configuration where a set of leaks to be detected is as disjoint as possible (i.e., spread out over a large area within geographic region 200), but where the set of leaks to be detected also contains the biggest leaks that may occur. In some scenarios, the deployment processor 116 determines a new sensor configuration based on an existing sensor configuration and adds new pollutant sensors 160, moves existing pollutant sensors 160, and/or replaces existing pollutant sensors 160 with different models. In some scenarios, there may be a preferred minimum distance between a sensor and equipment the sensor is configured to monitor, for example, to allow for installation, maintenance, and/or replacement of the pollutant sensor 160 without disrupting operation of the equipment itself (e.g., turning off the equipment to install the pollutant sensor 160).

In some aspects, the deployment processor 116 determines flight paths for drones and/or aerial vehicles that carry the pollutant sensors 160, orbital paths for satellites that carry the pollutant sensors 160, and/or ground paths for wheeled or tracked vehicles that carry the pollutant sensors 160. The flight paths, orbital paths, and/or ground paths may be determined based on a desired frequency of data (i.e., daily or weekly flyovers), cost of operation, or other suitable criteria.

Although only one instance of the computing device 110 is shown, several instances of the computing device 110 may be utilized, in various aspects. For example, the computing device 110 may be part of a distributed computing system and cooperate with other instances of the computing device 110 (not shown) to perform the steps described herein. In other aspects, the staging database 112, the sensor data processor 114, and/or the deployment processor 116 may be distributed across one, two, three, or more instances of the computing device 110. For example, a first instance of the computing device 110 may include the staging database 112, a second instance of the computing device 110 may include the sensor data processor 114, and third and fourth instances of the computing device 110 may include instances of the deployment processor 116.

The pollutant sensors 160 are configured to detect the presence (e.g., detected, not detected), rate of emission (e.g., kg per hour), and/or concentration level (e.g., number of particles in parts per million in a given volume or mass of particles) of pollutants. The pollutant sensors 160 may be selected from a plurality of available sensors having different pollutant detection sensitivities, spatial resolutions, temporal resolutions, purchase price, installation price, maintenance price, etc.

Network 150 may comprise one or more networks such as local area networks (LANs), wide area networks (WANs), enterprise networks, the Internet, etc., and may include one or more of wired and/or wireless portions. Computing device 110, pollutant source 120, environmental sensors 130, and data sources 140 may include at least one wired or wireless network interface that enables communication with each other (or an intermediate device, such as a Web server or database server) via network 150. Examples of such a network interface include but are not limited to an IEEE 802.11 wireless LAN (WLAN) wireless interface, a Worldwide Interoperability for Microwave Access (Wi-MAX) interface, an Ethernet interface, a Universal Serial Bus (USB) interface, a cellular network interface, a Bluetooth™ interface, or a near field communication (NFC) interface.

FIG. 2 shows a diagram of an example of a geographic region 200 for placement of pollutant sensors 160, shown as pollutant sensors 250, according to an example embodiment. In this example, the geographic region 200 represents a portion of the Permian basin in Texas and New Mexico. In various aspects, the deployment processor 116 is configured to divide a geographic region into a plurality of sub-regions based on environmental characteristics within the geographic region. For example, the deployment processor 116 may divide the geographic region 200 into sub-regions and/or groups of sub-regions, such as sub-region group 212 (including sub-regions 212-1, 212-2, 212-3), sub-region group 214, sub-region group 216, and sub-region group 218 based on the data within the staging database 112. The deployment processor 116 divides the geographic region 200 into areas with similar pollutant-related environmental characteristics, such as wind speed, wind direction, temperature, humidity, cloud cover, land use (e.g., buildings and structures such as well pads 220 and pipelines 222), elevation, and other suitable characteristics.

In some aspects, the deployment processor 116 identifies a sub-region as a contiguous cluster of areas that are within the geographic region 200 and have common (e.g., similar) dispersion effects on the pollutant. For example, a sub-region that encompasses a valley may generally channel methane down the valley in a direction consistent with typical wind flows. In some aspects, the identified sub-region has the common dispersion effects on the pollutant over different seasons. In other words, the deployment processor 116 is configured to identify sub-regions having similar dispersion effects for an entire season (i.e., spring, summer, fall, winter, dry season, monsoon season, etc.), or several seasons. In another embodiment, the deployment processor 116 identifies sub-regions having similar characteristics over a fixed period, such as 1 month, 3 months, 6 months, 12 months, etc. These approaches provide for improved sensor placement in that a location of a pollutant sensor 160 will be more relevant for a longer duration of the year, as opposed to extreme weather events, for example, only during or shortly after a rainstorm or high wind event. In other words, the deployment processor 116 identifies time-varying trends in the environmental characteristics and identifies the sub-regions based on the time-varying trends for improved consistency in sensor placement.

The deployment processor 116 may include a neural network model (not shown) that processes the data within the staging database to divide the geographic region 200 into sub-regions and determine locations for placement of the pollutant sensors 160. In some aspects, the neural network model is a convolutional neural network model, an autoencoder, time-modeling neural network (e.g., NeuralProphet), or other suitable neural network model. The neural network model may be configured to receive data from the staging database 112 and identify likely locations for pollutant leaks based on historical leak data and environmental characteristic data. For example, map data associated with a detected pollutant leak in a geographic region may be correlated with atmospheric data and/or topographical data to identify trends and/or patterns in dispersion of the pollutant.

In some embodiments, the neural network model is a deep neural network for spatial regression or classification. Examples of such networks include fully convolutional networks (e.g., U-net networks, memory-less convolutional networks), transformer-based networks, recurrent neural networks (e.g., long short-term memory networks), or other suitable networks.

In some aspects, the deployment processor 116 utilizes the neural network model to generate a stream of pollutant dispersion predictions (e.g., an estimated dispersion of the pollutant through the plurality of sub-regions), such as maps showing locations and concentrations of methane over a suitable time period (e.g., every 6 hours over 72 hours, every hour over 36 hours, etc.). The stream of pollutant dispersion predictions may be validated against measured and/or reported leak data within the staging database 112 for training the neural network model, for example. Advantageously, the staging database 112 may be configured with a common spatial and temporal discretization that does not need to be labeled and thus a neural network model may be trained in an unsupervised manner.

The deployment processor 116 may utilize a centroid model, for example, a k-means algorithm that represents each cluster by a single mean vector, to identify sub-regions having similar environmental characteristics and/or pollutant dispersion effects. Each sub-region may belong to one or more groups of sub-regions where each of groups of sub-regions have common dispersion effects on the pollutant. At least some sub-regions within a same group may be non-contiguous. For example, sub-regions 212-1, 212-2, and 212-3 represent sub-regions within a same sub-region group 212 and are not contiguous with each other.

In the embodiment shown in FIG. 2, the pollutant sensors 250 are generally placed downwind from closely spaced groups of pollutant sources, such as well pads 220. In some aspects, the deployment processor 116 performs a validation of the locations for sensor placement by performing a simulation using probabilities for pollutant emissions based on historical emissions. For example, the deployment processor 116 may utilize GHGSat data for detected methane leaks and state databases for reported methane leaks to determine whether or not the methane leaks are detected, how quickly the methane leaks are detected, etc.

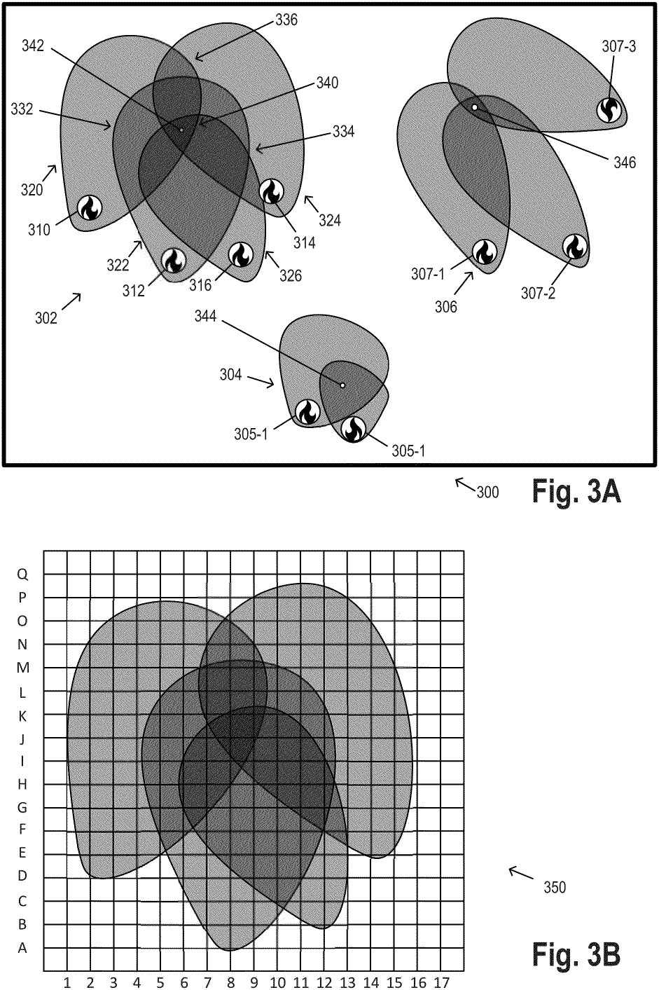

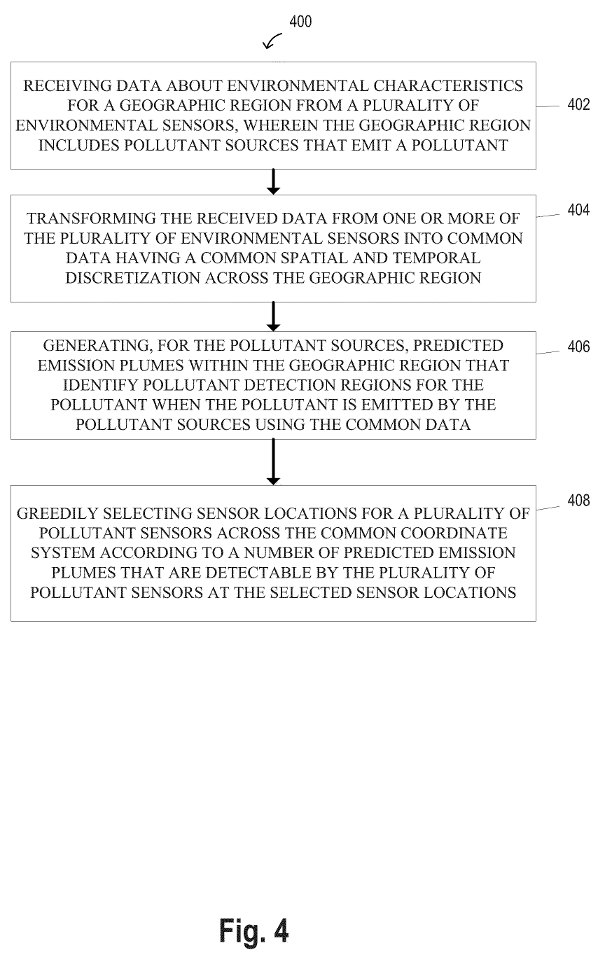

FIG. 3A shows a diagram of another example of a geographic region 300 for placement of pollutant sensors, according to aspects of the present disclosure. The geographic region 300 may be similar to geographic region 200, for example, and include pollutant sources 305, 307, 310, 312, 314, and 316 that represent various ground locations, buildings, equipment that may leak one or more pollutants (similar to pollutant sources 120). Although not shown in FIG. 3A for clarity, the geographic region 300 may include various topographic features such as hills, mountains, tree cover, grassland, structural features (buildings, parking lots, etc.), and/or weather patterns that affect dispersion of pollutants. The deployment processor 116 is configured to generate, for the pollutant sources 305, 307, 310, 312, 314, and 316, predicted emission regions within the geographic region that identify pollutant detection locations for the pollutant sources based on the environmental characteristics within the staging database 112 (e.g., the transformed common data). Some of the environmental characteristics may generally correspond to the topographic features, structural features, and/or weather patterns of the geographic region 300, in some examples.

In various examples, the deployment processor 116 is configured to simulate pollutant emissions from the pollutant sources 305, 307, 310, 312, 314, and 316 to generate corresponding predicted emission regions. In the example of FIG. 3A, the predicted emission regions are arranged in emission groups 302, 304, and 306 around adjacent pollutant sources, but other patterns of predicted emission regions may be generated in different geographic areas. In some examples, the deployment processor 116 is configured to generate a Gaussian plume model for the geographic region 300 and the pollutant sources 305, 307, 310, 312, 314, and 316. The deployment processor 116 may generate the Gaussian plume models sequentially, or in parallel (e.g., when suitable processing resources are available) using one “plume” for each pollutant source. In some scenarios, vectorization of the sensor data (e.g., using a common vector format) allows for parallel processing of the Gaussian plumes. In various examples and/or scenarios, pollutant sources may be modeled as a single point source, a string of sources, or a group of sources. For example, a pipeline may be modeled as a string of point sources or a single point source, a building with multiple leak points could be modeled as a group of sources, etc. A source of pollution that can be attributed to a specific physical location -- an identifiable, end-of-pipe “point.” As such, the term “point source” may refer to any discernible, confined and discrete conveyance, including but not limited to any oil and gas well pad, pipe, ditch, channel, tunnel, conduit, well, discrete fissure, container, rolling stock, concentrated animal feeding operation, or vessel or other floating craft, from which pollutants are or may be discharged.

Generation of the Gaussian plume models may have improved efficiency (e.g., less processing time, lower memory footprint) by converting sensor data from the environmental sensors into a common vector format. As one example, sensor data from satellites, aerial surveys, and sensors at pollutant sources may be mapped to a common vector format having a coordinate location on the common spatial and temporal discretization, a timestamp, a probability, and a concentration level (e.g., a vector: [X, Y, Z, Time, Probability, Concentration]). The common vector format maps the sensor data to the common spatial and temporal discretization with a common time scale so that direct comparisons may be made between sensor data from different sensor networks (e.g., satellite data vs. aerial data). In some examples, a predicted emission region has a single concentration level (e.g., 10 parts per million) across its entire area. In other examples, a predicted emission region has different pollutant concentrations at different points along the common spatial and temporal discretization. For example, concentration levels may be higher for coordinates that are closer to the pollutant source and lower for coordinates that are further (e.g., where the pollutant has dispersed).

FIG. 3B shows a diagram of an example common spatial and temporal discretization 350 for a portion of the geographic region 300 having the emission group 302, according to aspects of the present disclosure. The common spatial and temporal discretization 350 may be implemented as a single, large spatial and temporal discretization over the entire geographic region 300, or as multiple, separate spatial and temporal discretizations that cover sub-regions that are adjacent to the pollutant sources (e.g., pollutant sources 305, 307, 310, 312, 314, and 316). In some examples, the spatial and temporal discretizations may overlap. The common spatial and temporal discretization 350 as shown in FIG. 3B has two dimensional grid lines, with letters A through Q on a vertical axis and numbers 1 through 17 on a horizontal axis and is centered on the emission group 302. Coordinates or grid points within the common spatial and temporal discretization 350 may be referenced using the corresponding letters and numbers, such as B8, C9, etc. Although only two dimensions are shown, the common spatial and temporal discretization 350 may include three dimensions with a vertical dimension as a height above ground level, or relative to a reference ground level. The common spatial and temporal discretization 350 is a regular grid, but may be a rectilinear grid, curvilinear grid, or other suitable grid or system in other examples. In some examples, the common spatial and temporal discretization 350 corresponds to a common time discretization, for example, timestamps for 10 second time intervals, 10 minute time intervals, etc. In other words, the common spatial and temporal discretization 350 may have three dimensions (longitude, latitude, and time) or four dimensions (longitude, latitude, altitude, and time) with standardized intervals for coordinates. As one example, the common spatial and temporal discretization 350 has coordinates within its geographical area and time coverage with intervals of 5 seconds of longitude, every 5 seconds of latitude, 100 feet of altitude, and 30 minutes of time.

In the example shown in FIG. 3A, the deployment processor 116 generates a predicted emission region 320 for the pollutant source 310, a predicted emission region 322 for the pollutant source 312, a predicted emission region 324 for the pollutant source 314, and a predicted emission region 326 for the pollutant source 316 where the predicted emission regions 320, 322, 324, and 326 form the emission group 302. In a similar manner, the deployment processor 116 generates emission group 304 for the pollutant sources 305 and generates the emission group 306 for the pollutant sources 307. Predicted emission regions may be referred to as predicted emission plumes, for example, as a plume of methane or smoke, etc.

In various examples, two, three, or more predicted emission regions may overlap, for example, due to close proximity of pollutant sources (e.g., multiple oil and gas tank batteries/compressors in a small area). In these examples, it may be possible to place a single pollutant sensor that is able to detect pollutant emissions from multiple pollutant sources. In some examples, in order to identify such locations, the deployment processor 116 is configured to greedily select sets of coordinates from the common spatial and temporal discretization that have higher predicted emissions among the geographic region and identify coordinates or centroids of localized sub-regions or clusters that suitably cover the overlapping predicted emission regions. Where predicted emission regions overlap, corresponding pollutant concentrations are cumulative within the sub-regions.

As shown in FIG. 3A, the predicted emission regions 320, 322, 324, and 326 generally overlap in some sub-regions with darker shading showing areas of more overlap. For example, predicted emission region 320 overlaps predicted emission region 322 at a sub-region 332; predicted emission regions 322 and 324 overlap at a sub-region 334; predicted emission regions 320 and 324 overlap at a sub-region 336. However, a highest level of overlap is found in sub-region 340 (an overlapping sub-region), where predicted emission regions 320, 322, 324, and 326 overlap.

The deployment processor 116 may select a set of coordinates from the common spatial and temporal discretization that have higher predicted emissions among the geographic region 300. Using the common spatial and temporal discretization 350 shown in FIG. 3B as an example, the deployment processor 116 may select the set of coordinates to include coordinates K8, K9, J8, and J9 (corresponding to the emission group 302) and other coordinates (not shown) for the emission groups 304 and 306. In some examples, the deployment processor 116 selects coordinates that have a highest summation of predicted emission concentrations. In other words, the deployment processor 116 may sum values of predicted emission concentrations for coordinates on the common spatial and temporal discretization 350 and identify those coordinates having a first highest value, a second highest value, etc.

After determination of a pollutant sensor location, the deployment processor 116 iteratively determines additional pollutant sensor locations, for example, using a next highest predicted emission level from the common spatial and temporal discretization 350. In some examples, the deployment processor 116 omits predicted emission regions that are covered by previously determined pollutant sensor location. In the example shown in FIG. 3A, the deployment processor 116 may determine the location corresponding to centroid 342 as a first pollutant sensor location and then omit the predicted emission regions 320, 322, and 324 from subsequent iterations of determining sensor locations. For example, the deployment processor 116 may identify the centroid 342, then identify a centroid 344 for the emission group 304 (omitting the predicted emission regions 320, 322, and 324), then identify a centroid 346 for the emission group 306 (omitting the predicted emission regions 320, 322, and 324 and the emission group 304).

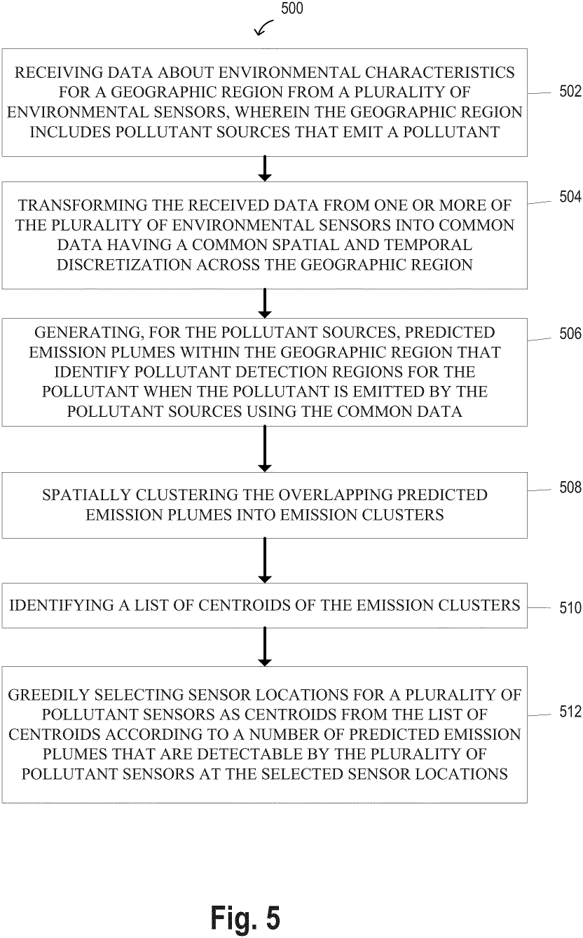

FIG. 4 shows a flowchart of another example method 400 of determining locations for pollutant sensors for pollutants from point sources, according to an example embodiment. Technical processes shown in these figures will be performed automatically unless otherwise indicated. In any given embodiment, some steps of a process may be repeated, perhaps with different parameters or data to operate on. Steps in an embodiment may also be performed in a different order than the top-to-bottom order that is laid out in FIG. 4. Steps may be performed serially, in a partially overlapping manner, or fully in parallel. Thus, the order in which steps of method 400 are performed may vary from one performance to the process of another performance of the process. Steps may also be omitted, combined, renamed, regrouped, be performed on one or more machines, or otherwise depart from the illustrated flow, provided that the process performed is operable and conforms to at least one claim. The steps of FIG. 4 may be performed by the computing device 110 (e.g., via the sensor data processor 114 and/or the deployment processor 116), or other suitable computing device.

At step 402, data about environmental characteristics for a geographic region is received from a plurality of environmental sensors. In some examples, at least some of the data about environmental characteristics is received from a data source (e.g., data source 140 as an intermediary processor of the data). In other words, the plurality of environmental sensors may include one or more data sources 140 that process data from environmental sensors 140. The geographic region includes pollutant sources that emit a pollutant. The geographic region corresponds to the geographic region 200 and/or the geographic region 300 and the data may be received, at the staging database 112 and/or the sensor data processor 114, from the pollutant sources 120, environmental sensors 130, and/or data sources 140, in various aspects. In some examples, the plurality of environmental sensors include satellite-based sensors, aerial-based sensors, and ground-based sensors.

At step 404, the received data from one or more of the plurality of environmental sensors is transformed into common data having a common spatial and temporal discretization across the geographic region. In an embodiment, for example, the sensor data processor 114 transforms the data within the staging database 112, as described above, to re-grid the data to a common spatial and temporal discretization (e.g., a same regular grid, rectilinear grid, or curvilinear grid). In some aspects, the sensor data processor 114 transforms (e.g., re-grids) the received data by interpolating first data about the environmental characteristics from a first data source to generate second data that is aligned with the common spatial and temporal discretization, where the common spatial and temporal discretization is associated with a second data source. Interpolating may include one or both of a temporal interpolation and a spatial interpolation. The first data source and the second data source may be selected from a land-use data source, a meteorological data source, a pollutant facility data source, a satellite-based pollutant emissions data source, or other suitable data sources, such as the data sources 140. Transforming the data may include converting sensor data from each of the plurality of environmental sensors into a common vector format. The common vector format may map the sensor data to the common spatial and temporal discretization with a common time scale (e.g., 15 minute intervals, 2 hour intervals).

At step 406, predicted emission plumes within the geographic region are generated for the pollutant sources, where the predicted emission plumes identify pollutant detection regions for the pollutant when the pollutant is emitted by the pollutant sources. The predicted emission plumes are generated using the common data, for example. In some examples, the deployment processor 116 may generate the predicted emission regions 320, 322, 324, and 326 as the predicted emission plumes. In some examples, step 406 includes simulating pollutant emissions from the pollutant sources (e.g., a subset of the pollutant sources 120 within the geographic region 200, or all of the pollutant sources 120 within the geographic region 200). In some examples, predicted emission regions of two or more pollutant sources overlap and pollutant concentrations are cumulative among overlapping predicted emission regions along the common spatial and temporal discretization. For example, the predicted emission regions 320, 322, and 324 overlap in sub-region 340 and coordinates within the sub-region 340 have pollutant concentrations corresponding to a combination of each of the pollutant concentrations from the predicted emission regions 320, 322, and 324. In some examples, a predicted emission region has different pollutant concentrations at different points along the common spatial and temporal discretization, while in other examples, the pollutant concentrations within a predicted emission region have a same value (for example, to reduce processing power for simulation). Simulating the pollutant emissions may include generating a Gaussian plume model for the geographic region and the pollutant sources, in some examples. Simulating the pollutant emissions from the pollutant sources may be performed in parallel using the Gaussian plume model, or in a serial progression, in various examples.

At step 408, sensor locations for a plurality of pollutant sensors are greedily selected across the common spatial and temporal discretization according to a number of predicted emission plumes that are detectable by the plurality of pollutant sensors at the selected sensor locations. In some examples, the deployment processor 116 is configured to greedily select sensor locations to prioritize a number of predicted emission plumes that are detectable by the pollutant sensors 160 (e.g., prioritizing higher numbers of detectable plumes). In the example shown in FIG. 3A, the deployment processor 116 may select the centroid 342, then the centroid 346, and then the centroid 344 for sensor locations that cover the emission groups 302, 306, and 304, respectively, where the emission groups are spatially clustered groups of overlapping predicted emission plumes. In some aspects, the deployment processor 116 determines a number of the pollutant sensors 160 for the placement and the locations of the pollutant sensors 160 that provide a minimum pollutant detectability threshold. The pollutant sensors 160 may be selected from a plurality of pollutant sensors having different pollutant detection sensitivities.

In some examples, step 408 includes spatially clustering the predicted emission plumes into emission clusters and greedily selecting the sensor locations from only coordinates of the common spatial and temporal discretization that are within the emission clusters. For example, the deployment processor 116 may identify the emission groups 302, 304, and 306 as respective clusters and select sensor locations from only those coordinates within the emission groups. This approach avoids wasted processing cycles on coordinates that would not cover any pollutant leaks. In some examples, the deployment processor 116 uses a density-based spatial clustering of applications with noise (DBSCAN) algorithm to generate the clusters. In other examples, the deployment processor 116 uses a k-means clustering algorithm, an expectation-maximization algorithm, a balanced iterative reducing and clustering using hierarchies (BIRCH) algorithm, or other suitable clustering algorithm.

In some examples, step 408 includes spatially clustering the predicted emission plumes into emission clusters, identifying centroid locations of the emission clusters, and greedily selecting the sensor locations from only the centroid locations. For example, the deployment processor 116 may identify the centroids 342, 344, and 346 of the emission groups 302, 304, and 306 and only select from among the identified centroids, instead of coordinates that would not cover any pollutant leaks, or would cover only a few pollutant leaks.

In some examples, step 408 includes omitting coordinates of the common spatial and temporal discretization that correspond to preconfigured exclusionary zones. For example, the deployment processor 116 may omit coordinates that are located on or near roads, private property, or inaccessible areas (e.g., rivers, marshes, steep terrain). In other examples, the exclusionary zones include coordinates that are not located within suitable placement areas. In one such example, the exclusionary zone includes any areas outside of well pads for natural gas infrastructure.

In some examples, step 408 includes greedily selecting coordinates of the common spatial and temporal discretization that prioritize or maximize detectability of preselected predicted emission plumes. In some such examples, the preselected predicted emission plumes correspond to equipment that is known to be more likely to leak the pollutant (e.g., older equipment, equipment with a history of leaks).

In some examples, step 408 includes greedily selecting coordinates of the common spatial and temporal discretization to prioritize or maximize geographic coverage of the plurality of pollutant sensors. For example, the deployment processor 116 may select coordinates that are more distant from each other to reduce overlap of sensor coverage.

In some examples, step 408 includes greedily selecting coordinates of the common spatial and temporal discretization to minimize detection time for preselected predicted emission plumes. For example, the deployment processor 116 may select coordinates that are a shorter distance or downwind from preselected predicted emission plumes that correspond to equipment that is more likely to experience a substantial leak to improve a response time for addressing the leak.

In some examples, the greedy selection of coordinates is done in parallel for the different emission groups. In other words, after spatial clustering, a distributed system or multi-threaded processor may perform a first greedy selection of coordinates for the emission group 302 in parallel with second and third greedy selections for the emission groups 304 and 306.

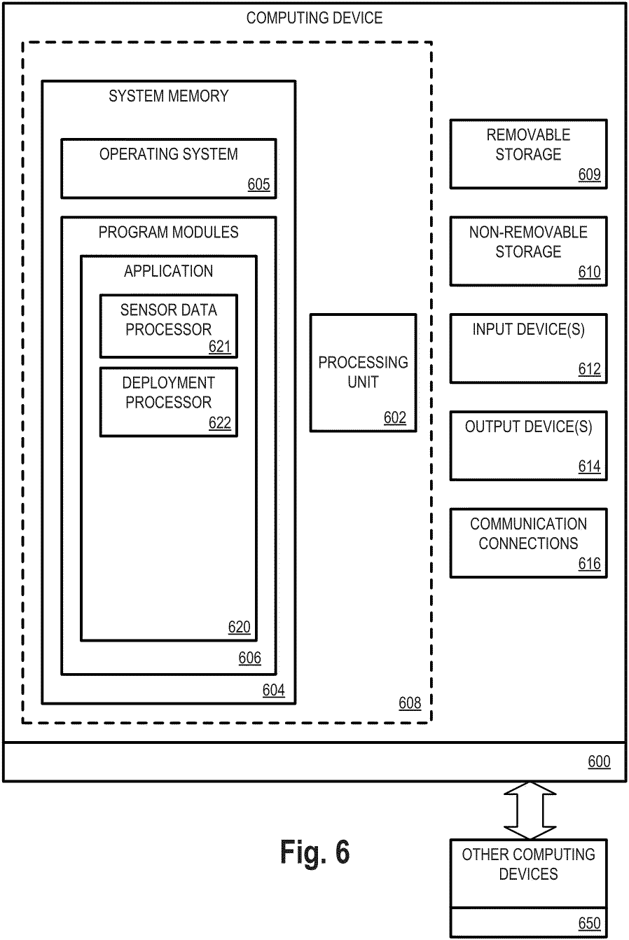

FIG. 5 shows a flowchart of another example method 500 of determining locations for pollutant sensors for pollutants from point sources, according to an example embodiment. Technical processes shown in these figures will be performed automatically unless otherwise indicated. In any given embodiment, some steps of a process may be repeated, perhaps with different parameters or data to operate on. Steps in an embodiment may also be performed in a different order than the top-to-bottom order that is laid out in FIG. 5. Steps may be performed serially, in a partially overlapping manner, or fully in parallel. Thus, the order in which steps of method 500 are performed may vary from one performance to the process of another performance of the process. Steps may also be omitted, combined, renamed, regrouped, be performed on one or more machines, or otherwise depart from the illustrated flow, provided that the process performed is operable and conforms to at least one claim. The steps of FIG. 5 may be performed by the computing device 110 (e.g., via the sensor data processor 114 and/or the deployment processor 116), or other suitable computing device.

At step 502, data about environmental characteristics for a geographic region is received from a plurality of environmental sensors. The geographic region includes pollutant sources that emit a pollutant. The geographic region corresponds to the geographic region 200 and/or the geographic region 300 and the data may be received, at the staging database 112 and/or the sensor data processor 114, from the pollutant sources 120, environmental sensors 130, and/or data sources 140, in various aspects. In some examples, the plurality of environmental sensors include satellite-based sensors, aerial-based sensors, and ground-based sensors.

At step 504, the received data from one or more of the plurality of environmental sensors is transformed into common data having a common spatial and temporal discretization across the geographic region. In an embodiment, for example, the sensor data processor 114 transforms the data within the staging database 112, as described above, to re-grid the data to a common spatial and temporal discretization (e.g., a same regular grid, rectilinear grid, or curvilinear grid). In some aspects, the sensor data processor 114 transforms (e.g., re-grids) the received data by interpolating first data about the environmental characteristics from a first data source to generate second data that is aligned with the common spatial and temporal discretization, where the common spatial and temporal discretization is associated with a second data source.

At step 506, predicted emission plumes within the geographic region are generated for the pollutant sources, where the predicted emission plumes identify pollutant detection regions for the pollutant when the pollutant is emitted by the pollutant sources.

At step 508, the overlapping predicted emission plumes are spatially clustered into emission clusters. For example, the deployment processor 116 may spatially cluster predicted emission regions 320, 322, and 324 into an emission group 302.

At step 510, a list of centroids of the emission clusters are identified. For example, a list of centroid for the geographic region 300 includes the centroids 342, 344, and 346.

At step 512, sensor locations for a plurality of pollutant sensors are greedily selected as centroids from the list of centroids according to a number of predicted emission plumes that are detectable by the plurality of pollutant sensors at the selected sensor locations. In some examples, step 512 includes greedily selecting centroids that prioritize detectability of preselected predicted emission plumes. In some examples, step 512 includes removing greedily selected centroids from the list of centroids before selecting a next centroid. In some examples, step 512 includes identifying centroids of the greedily selected centroids as the sensor locations.

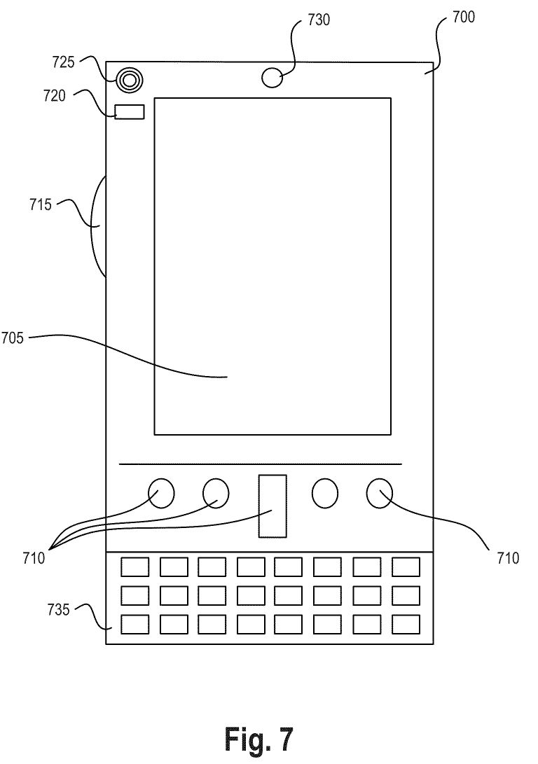

FIGS. 6, 7, and 8 and the associated descriptions provide a discussion of a variety of operating environments in which aspects of the disclosure may be practiced. However, the devices and systems illustrated and discussed with respect to FIGS. 6-8 are for purposes of example and illustration and are not limiting of a vast number of computing device configurations that may be utilized for practicing aspects of the disclosure, as described herein.

FIG. 6 is a block diagram illustrating physical components (e.g., hardware) of a computing device 600 with which aspects of the disclosure may be practiced. The computing device components described below may have computer executable instructions for implementing a pollutant sensor deployment application 620 on a computing device (e.g., computing device 110), including computer executable instructions for pollutant sensor deployment application 620 that can be executed to implement the methods disclosed herein. In a basic configuration, the computing device 600 may include at least one processing unit 602 and a system memory 604. Depending on the configuration and type of computing device, the system memory 604 may comprise, but is not limited to, volatile storage (e.g., random access memory), non-volatile storage (e.g., read-only memory), flash memory, or any combination of such memories. The system memory 604 may include an operating system 605 and one or more program modules 606 suitable for running pollutant sensor deployment application 620, such as one or more components with regard to FIG. 1 and, in particular, sensor data processor 621 (e.g., corresponding to sensor data processor 114), and deployment processor 622 (e.g., corresponding to deployment processor 116).

The operating system 605, for example, may be suitable for controlling the operation of the computing device 600. Furthermore, aspects of the disclosure may be practiced in conjunction with a graphics library, other operating systems, or any other application program and is not limited to any particular application or system. This basic configuration is illustrated in FIG. 6 by those components within a dashed line 608. The computing device 600 may have additional features or functionality. For example, the computing device 600 may also include additional data storage devices (removable and/or non-removable) such as, for example, magnetic disks, optical disks, or tape. Such additional storage is illustrated in FIG. 6 by a removable storage device 609 and a non-removable storage device 610.

As stated above, a number of program modules and data files may be stored in the system memory 604. While executing on the processing unit 602, the program modules 606 (e.g., pollutant sensor deployment application 620) may perform processes including, but not limited to, the aspects, as described herein. Other program modules that may be used in accordance with aspects of the present disclosure, and in particular for determining locations for pollutant sensors, may include sensor data processor 621 and deployment processor 622.

Furthermore, aspects of the disclosure may be practiced in an electrical circuit comprising discrete electronic elements, packaged or integrated electronic chips containing logic gates, a circuit utilizing a microprocessor, or on a single chip containing electronic elements or microprocessors. For example, aspects of the disclosure may be practiced via a system-on-a-chip (SOC) where each or many of the components illustrated in FIG. 6 may be integrated onto a single integrated circuit. Such an SOC device may include one or more processing units, graphics units, communications units, system virtualization units and various application functionality all of which are integrated (or “burned”) onto the chip substrate as a single integrated circuit. When operating via an SOC, the functionality, described herein, with respect to the capability of client to switch protocols may be operated via application-specific logic integrated with other components of the computing device 600 on the single integrated circuit (chip). Aspects of the disclosure may also be practiced using other technologies capable of performing logical operations such as, for example, AND, OR, and NOT, including but not limited to mechanical, optical, fluidic, and quantum technologies. In addition, aspects of the disclosure may be practiced within a general purpose computer or in any other circuits or systems.

The computing device 600 may also have one or more input device(s) 612 such as a keyboard, a mouse, a pen, a sound or voice input device, a touch or swipe input device, etc. The output device(s) 614 such as a display, speakers, a printer, etc. may also be included. The aforementioned devices are examples and others may be used. The computing device 600 may include one or more communication connections 616 allowing communications with other computing devices 650. Examples of suitable communication connections 616 include, but are not limited to, radio frequency (RF) transmitter, receiver, and/or transceiver circuitry; universal serial bus (USB), parallel, and/or serial ports.

The term computer readable media as used herein may include computer storage media. Computer storage media may include volatile and nonvolatile, removable and non-removable media implemented in any method or technology for storage of information, such as computer readable instructions, data structures, or program modules. The system memory 604, the removable storage device 609, and the non-removable storage device 610 are all computer storage media examples (e.g., memory storage). Computer storage media may include RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other article of manufacture which can be used to store information and which can be accessed by the computing device 600. Any such computer storage media may be part of the computing device 600. Computer storage media does not include a carrier wave or other propagated or modulated data signal.

Communication media may be embodied by computer readable instructions, data structures, program modules, or other data in a modulated data signal, such as a carrier wave or other transport mechanism, and includes any information delivery media. The term “modulated data signal” may describe a signal that has one or more characteristics set or changed in such a manner as to encode information in the signal. By way of example, and not limitation, communication media may include wired media such as a wired network or direct-wired connection, and wireless media such as acoustic, radio frequency (RF), infrared, and other wireless media.

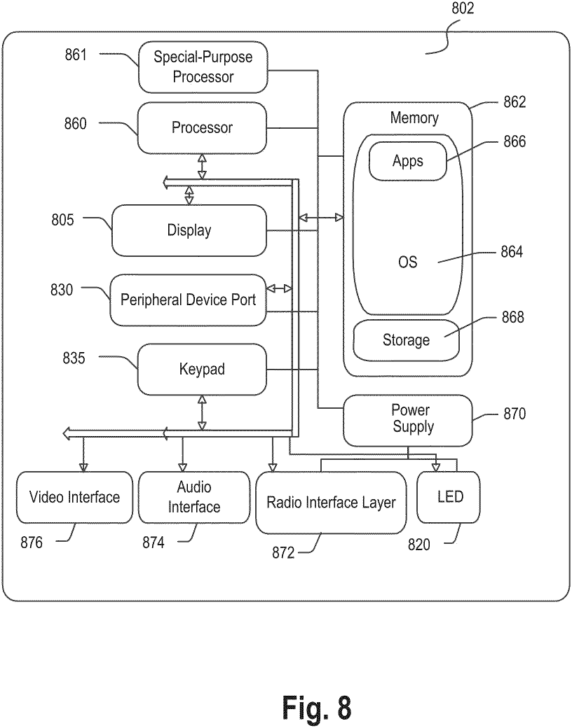

FIGS. 7 and 8 illustrate a mobile computing device 700, for example, a mobile telephone, a smart phone, wearable computer (such as a smart watch), a tablet computer, a laptop computer, and the like, with which aspects of the disclosure may be practiced. In some aspects, the client may be a mobile computing device. With reference to FIG. 7, one aspect of a mobile computing device 700 for implementing the aspects is illustrated. In a basic configuration, the mobile computing device 700 is a handheld computer having both input elements and output elements. The mobile computing device 700 typically includes a display 705 and one or more input buttons 710 that allow the user to enter information into the mobile computing device 700. The display 705 of the mobile computing device 700 may also function as an input device (e.g., a touch screen display). If included, an optional side input element 715 allows further user input. The side input element 715 may be a rotary switch, a button, or any other type of manual input element. In alternative aspects, mobile computing device 700 may incorporate more or less input elements. For example, the display 705 may not be a touch screen in some aspects. In yet another alternative embodiment, the mobile computing device 700 is a portable phone system, such as a cellular phone. The mobile computing device 700 may also include an optional keypad 735. Optional keypad 735 may be a physical keypad or a “soft” keypad generated on the touch screen display. In various aspects, the output elements include the display 705 for showing a graphical user interface (GUI), a visual indicator 720 (e.g., a light emitting diode), and/or an audio transducer 725 (e.g., a speaker). In some aspects, the mobile computing device 700 incorporates a vibration transducer for providing the user with tactile feedback. In yet another aspect, the mobile computing device 700 incorporates input and/or output ports, such as an audio input (e.g., a microphone jack), an audio output (e.g., a headphone jack), and a video output (e.g., a HDMI port) for sending signals to or receiving signals from an external device.

FIG. 8 is a block diagram illustrating the architecture of one aspect of a mobile computing device. That is, the mobile computing device 700 can incorporate a system (e.g., an architecture) 802 to implement some aspects. In one embodiment, the system 802 is implemented as a “smart phone” capable of running one or more applications (e.g., browser, e-mail, calendaring, contact managers, messaging clients, games, and media clients/players). In some aspects, the system 802 is integrated as a computing device, such as an integrated personal digital assistant (PDA) and wireless phone.

One or more application programs 866 may be loaded into the memory 862 and run on or in association with the operating system 864. Examples of the application programs include phone dialer programs, e-mail programs, personal information management (PIM) programs, word processing programs, spreadsheet programs, Internet browser programs, messaging programs, and so forth. The system 802 also includes a non-volatile storage area 868 within the memory 862. The non-volatile storage area 868 may be used to store persistent information that should not be lost if the system 802 is powered down. The application programs 866 may use and store information in the non-volatile storage area 868, such as email or other messages used by an email application, and the like. A synchronization application (not shown) also resides on the system 802 and is programmed to interact with a corresponding synchronization application resident on a host computer to keep the information stored in the non-volatile storage area 868 synchronized with corresponding information stored at the host computer.

The system 802 has a power supply 870, which may be implemented as one or more batteries. The power supply 870 may further include an external power source, such as an AC adapter or a powered docking cradle that supplements or recharges the batteries.

The system 802 may also include a radio interface layer 872 that performs the function of transmitting and receiving radio frequency communications. The radio interface layer 872 facilitates wireless connectivity between the system 802 and the “outside world,” via a communications carrier or service provider. Transmissions to and from the radio interface layer 872 are conducted under control of the operating system 864. In other words, communications received by the radio interface layer 872 may be disseminated to the application programs 866 via the operating system 864, and vice versa.

The visual indicator 820 may be used to provide visual notifications, and/or an audio interface 874 may be used for producing audible notifications via an audio transducer 825 (e.g., audio transducer 825 illustrated in FIG. 8). In the illustrated embodiment, the visual indicator 820 is a light emitting diode (LED) and the audio transducer 825 may be a speaker. These devices may be directly coupled to the power supply 870 so that when activated, they remain on for a duration dictated by the notification mechanism even though the processor 860 and other components might shut down for conserving battery power. The LED may be programmed to remain on indefinitely until the user takes action to indicate the powered-on status of the device. The audio interface 874 is used to provide audible signals to and receive audible signals from the user. For example, in addition to being coupled to the audio transducer 825, the audio interface 874 may also be coupled to a microphone to receive audible input, such as to facilitate a telephone conversation. In accordance with aspects of the present disclosure, the microphone may also serve as an audio sensor to facilitate control of notifications, as will be described below. The system 802 may further include a video interface 876 that enables an operation of peripheral device 830 (e.g., on-board camera) to record still images, video stream, and the like.

A mobile computing device 800 implementing the system 802 may have additional features or functionality. For example, the mobile computing device 800 may also include additional data storage devices (removable and/or non-removable) such as, magnetic disks, optical disks, or tape. Such additional storage is illustrated in FIG. 8 by the non-volatile storage area 868.

Data/information generated or captured by the mobile computing device 800 and stored via the system 802 may be stored locally on the mobile computing device 800, as described above, or the data may be stored on any number of storage media that may be accessed by the device via the radio interface layer 872 or via a wired connection between the mobile computing device 800 and a separate computing device associated with the mobile computing device 800, for example, a server computer in a distributed computing network, such as the Internet. As should be appreciated such data/information may be accessed via the mobile computing device 800 via the radio interface layer 872 or via a distributed computing network. Similarly, such data/information may be readily transferred between computing devices for storage and use according to well-known data/information transfer and storage means, including electronic mail and collaborative data/information sharing systems.

As should be appreciated, FIGS. 7 and 8 are described for purposes of illustrating the present methods and systems and is not intended to limit the disclosure to a particular sequence of steps or a particular combination of hardware or software components.

The description and illustration of one or more aspects provided in this application are not intended to limit or restrict the scope of the disclosure as claimed in any way. The aspects, examples, and details provided in this application are considered sufficient to convey possession and enable others to make and use the best mode of claimed disclosure. The claimed disclosure should not be construed as being limited to any aspect, example, or detail provided in this application. Regardless of whether shown and described in combination or separately, the various features (both structural and methodological) are intended to be selectively included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

What is claimed is:

1. A method for pollutant sensor placement for pollutants from point sources, the method comprising:
receiving data about environmental characteristics for a geographic region from a plurality of environmental sensors, wherein the geographic region includes pollutant sources that emit a pollutant;
transforming the received data from one or more of the plurality of environmental sensors into common data having a common spatial and temporal discretization across the geographic region;
generating for the pollutant sources predicted emission plumes within the geographic region using the common data, wherein the predicted emission plumes identify pollutant detection regions for the pollutant when the pollutant is emitted by the pollutant sources; and
greedily selecting sensor locations for a plurality of pollutant sensors across the common spatial and temporal discretization according to a number of predicted emission plumes that are detectable by the plurality of pollutant sensors at the selected sensor locations.

2. The method of claim 1, wherein greedily selecting the sensor locations comprises:
spatially clustering the predicted emission plumes into emission clusters;
greedily selecting the sensor locations from only coordinates of the common spatial and temporal discretization that are within the emission clusters.

3. The method of claim 1, wherein greedily selecting the sensor locations comprises:
spatially clustering the predicted emission plumes into emission clusters;
identifying centroid locations of the emission clusters; and
greedily selecting the sensor locations from only the centroid locations.

4. The method of claim 1, wherein receiving the data about environmental characteristics comprises receiving at least some of the data from data sources that process data from environmental sensors.

5. The method of claim 1, wherein greedily selecting the sensor locations comprises omitting coordinates of the common spatial and temporal discretization that correspond to preconfigured exclusionary zones.

6. The method of claim 1, wherein greedily selecting the sensor locations comprises greedily selecting coordinates of the common spatial and temporal discretization that prioritize detectability of preselected predicted emission plumes.

7. The method of claim 1, wherein greedily selecting the sensor locations comprises greedily selecting coordinates of the common spatial and temporal discretization to prioritize geographic coverage of the plurality of pollutant sensors.

8. The method of claim 1, wherein greedily selecting the sensor locations comprises greedily selecting coordinates of the common spatial and temporal discretization to minimize detection time for preselected predicted emission plumes.

9. A method for pollutant sensor placement for pollutants from point sources, the method comprising:
receiving data about environmental characteristics for a geographic region from a plurality of environmental sensors, wherein the geographic region includes pollutant sources that emit a pollutant;
transforming the received data from one or more of the plurality of environmental sensors into common data having a common spatial and temporal discretization across the geographic region;
generating, for the pollutant sources, predicted emission plumes within the geographic region using the common data, wherein the predicted emission plumes identify pollutant detection regions for the pollutant when the pollutant is emitted by the pollutant sources;
spatially clustering the overlapping predicted emission plumes into emission clusters;
identifying a list of centroids of the emission clusters; and
greedily selecting sensor locations for a plurality of pollutant sensors as centroids from the list of centroids according to a number of predicted emission plumes that are detectable by the plurality of pollutant sensors at the selected sensor locations.

10. The method of claim 9, wherein greedily selecting the sensor locations comprises greedily selecting centroids that prioritize detectability of preselected predicted emission plumes.

11. The method of claim 9, wherein greedily selecting the sensor locations comprises removing greedily selected centroids from the list of centroids before selecting a next centroid.

12. The method of claim 11, wherein greedily selecting the sensor locations comprises identifying centroids of the greedily selected centroids as the sensor locations.

13. A system for pollutant sensor placement for pollutants from point sources, the system comprising:
a staging database configured to receive data about environmental characteristics for a geographic region from a plurality of environmental sensors, wherein the geographic region includes pollutant sources that emit a pollutant;
a sensor data processor configured to transform the received data from one or more of the plurality of environmental sensors into common data having a common spatial and temporal discretization across the geographic region; and
a deployment processor configured to:
generate, for the pollutant sources, predicted emission plumes within the geographic region that identify pollutant detection regions for the pollutant when the pollutant is emitted by the pollutant sources using the common data; and
greedily select sensor locations for a plurality of pollutant sensors across the common spatial and temporal discretization according to a number of predicted emission plumes that are detectable by the plurality of pollutant sensors at the selected sensor locations.

14. The system of claim 13, wherein the deployment processor is further configured to:
spatially cluster the predicted emission plumes into emission clusters;
greedily select the sensor locations from only coordinates of the common spatial and temporal discretization that are within the emission clusters.

15. The system of claim 13, wherein the deployment processor is further configured to:
spatially cluster the predicted emission plumes into emission clusters;
identify centroid locations of the emission clusters; and
greedily select the sensor locations from only the centroid locations.

16. The system of claim 15, wherein the deployment processor is further configured to:
receive at least some of the data from data sources that process data from environmental sensors.

17. The system of claim 13, wherein the deployment processor is further configured to omit coordinates of the common spatial and temporal discretization that correspond to preconfigured exclusionary zones.

18. The system of claim 13, wherein the deployment processor is further configured to greedily select coordinates of the common spatial and temporal discretization that prioritize detectability of preselected predicted emission plumes.

19. The system of claim 13, wherein the deployment processor is further configured to greedily select coordinates of the common spatial and temporal discretization to prioritize geographic coverage of the plurality of pollutant sensors.

20. The system of claim 13, wherein the deployment processor is further configured to greedily select coordinates of the common spatial and temporal discretization to minimize detection time for preselected predicted emission plumes.
